(19) United States
(12) Patent Application Publication
(10) Pub. No.: US 2014/0333289 A1
(43) Pub. Date: Nov. 13, 2014

(54) CURRENT DETECTION DEVICE FOR MULTI-SENSOR ARRAY

(71) Applicants: Jae-Kyung Wee, Seoul (KR); Young-San Shin, Seoul (KR)

(72) Inventors: Jae-Kyung Wee, Seoul (KR); Young-San Shin, Seoul (KR)

(73) Assignee: FOUNDATION OF SOONGSIL UNIVERSITY-INDUSTRY COOPERATION, Seoul (KR)

(21) Appl. No.: 14/363,688

(22) PCT Filed: Mar. 14, 2012
(86) PCT No.: PCT/KR2012/001825

§ 371 Date: Jun. 6, 2014

(30) Foreign Application Priority Data
Dec. 8, 2011 (KR) 10-2011-0130860

(51) Int. Cl. G01R 19/00; G01R 19/22

(52) U.S. Cl. CPC G01R 19/0092; G01R 19/22
USPC 324/120

(57) ABSTRACT

A current detection device for a multi-sensor array is provided. The current detection device includes a current input unit, a current conversion unit, a digital conversion unit, and a voltage applying unit. The current input unit amplifies a plurality of current signals input from a multi-sensor array according to a predetermined current minor ratio, and fixes each of node voltages to which the plurality of current signals are input. The current conversion unit converts each of the amplified current signals into an amplified voltage signal using a plurality of feedback resistors and an operational amplifier which are connected in parallel. The digital conversion unit converts each of the amplified voltage signals converted by the current conversion unit into a digital value. The voltage applying unit generates voltages for driving each of the multi-sensor array, the current input unit, the current conversion unit, and the digital conversion unit, and applies the generated voltages thereto.

### CROSS-REFERENCE TO RELATED APPLICATION

This application claims priority to and the benefit of Korean Patent Application No. 2011-0130860, filed on Dec. 8, 2011, the disclosure of which is incorporated herein by reference in its entirety.

### BACKGROUND

An exemplary embodiment relates to a current detection device for a multi-sensor array, and more particularly, to a current detection device for a multi-sensor array capable of detecting signals of the multi-sensor array with minimum power consumption.

### DISCUSSION OF RELATED ART

According to increase of health and environmental concerns, demand for a portable sensor system capable of detecting bio-signals or harmful environment materials in real time is increasing. In order to implement such a system, a low power and high performance circuit capable of detecting a sensor signal as well as a high-density sensor array is required.

In the field of such a sensor signal detection circuit, the sensor signal is detected based on change in conductivity or current. A conventional method of detecting the sensor signal is largely classified as a current-to-time (C-T) conversion method or a current-to-voltage (C-V) conversion method.

FIG. 1 is a circuit diagram illustrating a conventional C-T conversion method.

Referring to FIG. 1, the C-T conversion method charges a current of a sensor using an integrator into a capacitor, and converts a frequency of a generated pulse wave into a digital value through a circuit such as a counter, etc. The C-T conversion method has an advantage capable of converting the current of the sensor into the digital value without an additional digital conversion circuit.

However, generally, since the current of the sensor has a very small value, the C-T conversion method has a disadvantage in that a lot of time is required when converting the current of the sensor into the digital value and a detection speed is different due to a different current value.

When increasing the number of sensors, this acts as a limited factor in a channel conversion, etc. To solve this problem, a high-speed clock and a current amplifier are required, but this leads to an increase in area and power consumption.

FIG. 2 is a circuit diagram illustrating a conventional C-V conversion method.

Referring to FIG. 2, the C-V conversion method converts a current of a sensor into a voltage by a feedback method using a resistor. The C-V conversion method has an advantage capable of very quickly detecting a signal of a carbon nanotube (CNT) sensor according to a bandwidth of an amplifier.

The C-V conversion method requires a large resistance value in order to convert a very small current value of a sensor into a voltage like the C-T conversion method, and requires a considerably large area in order to implement an on-chip device when there are a large number of sensors.

Consequently, the C-T conversion method and the C-V conversion method require a considerably large area and power consumption in order to amplify a small current signal of a sensor. Specifically, when implementing the large number of sensors as the on-chip device, use of a passive device occupying a large area acts as a disadvantage in costs.

In a conventional paper related to the present invention titled “A 160 dB Equivalent Dynamic Range Auto-Scaling Interface for Resistive Gas Sensors Arrays” disclosed by M. Grassi and P. Malcovati in 2007, a detection method using a feedback resistor and current-voltage conversion was proposed. However, a considerably large resistor is required due to a low current of a sensor.

In another paper related to the present invention titled “A New and Fast-Readout Interface for Resistive Chemical Sensors” disclosed by Lessandro Depari and Alessandra Flammini in 2009, a detection method using a current integration value was proposed. However, an additional amplifier is required in order to increase a detection speed.

### SUMMARY OF THE INVENTION

One or more exemplary embodiments are directed to a current detection device for a multi-sensor array capable of detecting signals of the multi-sensor array by minimizing power consumption and area.

According to an aspect of an exemplary embodiment, there is provided a current detection device, including: a current input unit configured to amplify a plurality of current signals input from a multi-sensor array according to a predetermined current mirror ratio, and fix each of node voltages to which the plurality of current signals are input; a current conversion unit configured to convert each of the amplified current signals into an amplified voltage signal using a plurality of feedback resistors and an operational amplifier which are connected in parallel; a digital conversion unit configured to convert each of the amplified voltage signals converted by the current conversion unit into a digital value; and a voltage applying unit configured to generate voltages for driving each of the multi-sensor array, the current input unit, the current conversion unit, and the digital conversion unit, and apply the generated voltages thereto.

### BRIEF DESCRIPTION OF THE DRAWINGS

The above and other features and advantages of the exemplary embodiments will become more apparent to those of ordinary skill in the art with reference to the attached drawings in which:

FIG. 1 is a circuit diagram illustrating a conventional current-to-time (C-T) conversion method;

FIG. 2 is a circuit diagram illustrating a conventional current-to-voltage (C-V) conversion method;

FIG. 3 is a block diagram illustrating an entire signal detection system including a current detection device for a multi-sensor array according to an exemplary embodiment of the present;

FIG. 4 is a block diagram illustrating a detailed construction of a detection unit according to an exemplary embodiment;

FIG. 5 is a circuit diagram illustrating a construction of the detection unit shown in FIG. 4;

FIG. 6 is a circuit diagram illustrating an active input current mirror constituting a current input unit;

FIG. 7 is a graph illustrating nonlinear characteristics of a voltage signal amplified by a current conversion unit;

FIG. 8 is a circuit diagram illustrating an operational amplifier included in the current conversion unit;

FIGS. 9A and 9B are diagrams illustrating a circuit and an operation method of a digital conversion unit;

FIG. 10 is a circuit diagram illustrating a detailed construction of a voltage applying unit; and

FIG. 11 is a graph illustrating a change of an entire area according to a current mirror ratio (CMR).

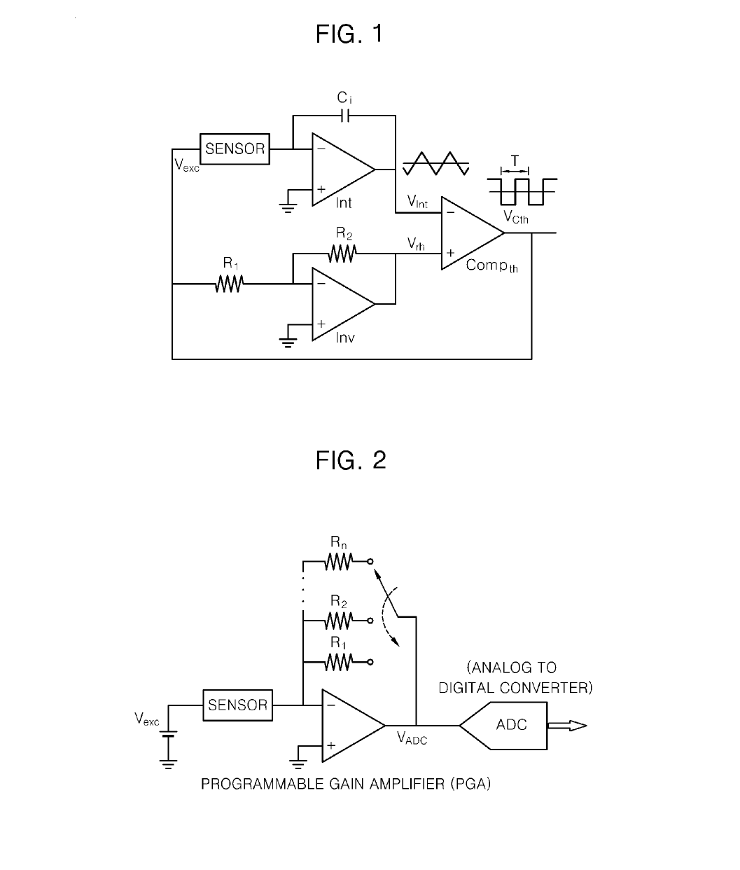

### DETAILED DESCRIPTION OF EMBODIMENTS

Hereinafter, a current detection device for a multi-sensor array according to embodiments of the inventive concept will be described below in more detail with reference to the accompanying drawings.

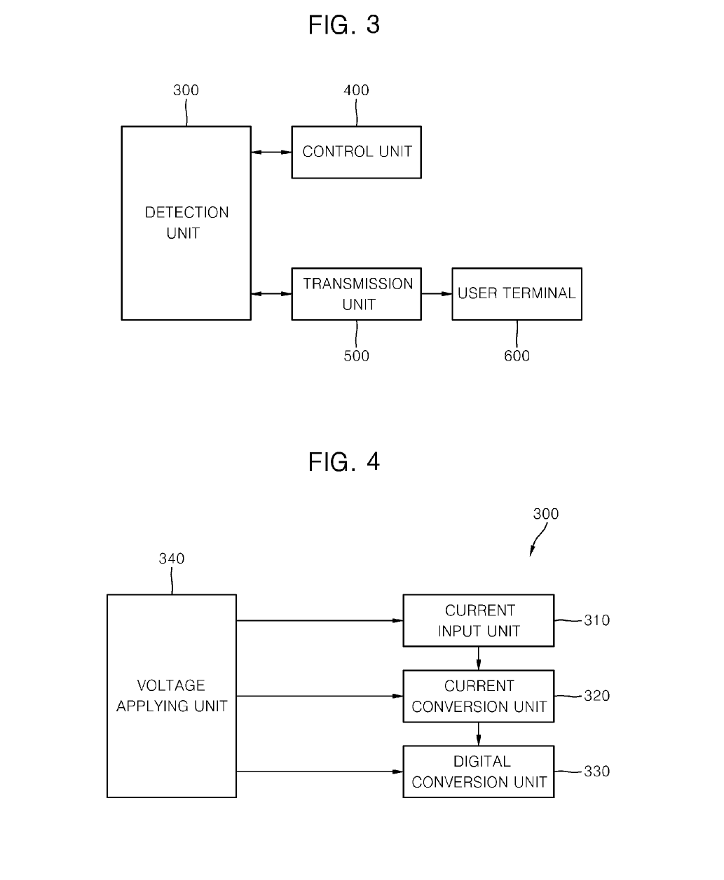

FIG. 3 is a block diagram illustrating an entire signal detection system including a current detection device for a multi-sensor array according to an exemplary embodiment.

Referring to FIG. 3, a signal detection system may include a detection unit 300, a control unit 400, a transmission unit 500, and a user terminal 600. A current detection device according to the present invention may be the detection unit 300.

The detection unit 300 may detect by converting an analog current signal input from the multi-sensor array into a digital signal. At this time, the control unit 400 may control a detection process of the detection unit 300, and the transmission unit 500 may transmit the detected digital signal to the user terminal 600.

FIG. 4 is a block diagram illustrating a detailed construction of a detection unit according to an exemplary embodiment.

Referring to FIG. 4, the detection unit 300 may include a current input unit 310, a current conversion unit 320, a digital conversion unit 330, and a voltage applying unit 340.

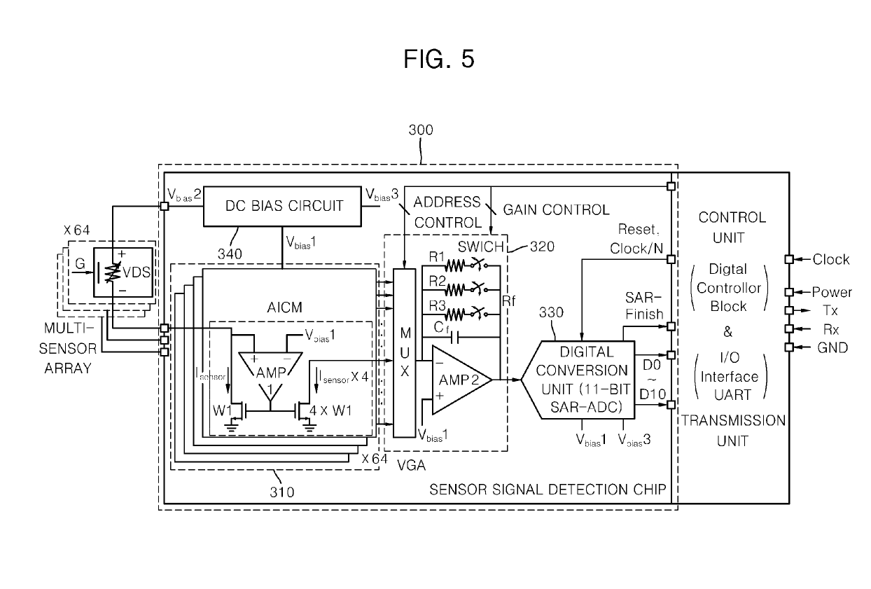

Further, FIG. 5 is a circuit diagram illustrating a construction of the detection unit 300 shown in FIG. 4.

Referring to FIG. 5, the current input unit 310 may include a plurality of active input current minors (AICMs), and the current conversion unit 320 may include a multiplexer (MUX) and a variable gain amplifier (VGA).

Further, the digital conversion unit 330 may have a construction of an 11-bit successive approximation register-analog to digital converter (SAR-ADC), and the voltage applying unit 340 may be implemented using a direct current (DC) bias circuit and a buffer.

Hereinafter, an operation of each component of the present invention shown in FIGS. 4 and 5 will be described in detail.

The current input unit 310 may amplify a plurality of current signals input from the multi-sensor array according to a predetermined current minor ratio (CMR), and fix a node voltage of each of nodes to which the plurality of current signals are input. At this time, the current input unit 310 may fix each node voltage using the AICM as a differential amplifier.

Specifically, the current input unit 310 may amplify each current signal by the CMR, and may include the plurality of AICMs corresponding to the number of sensors constituting the multi-sensor array.

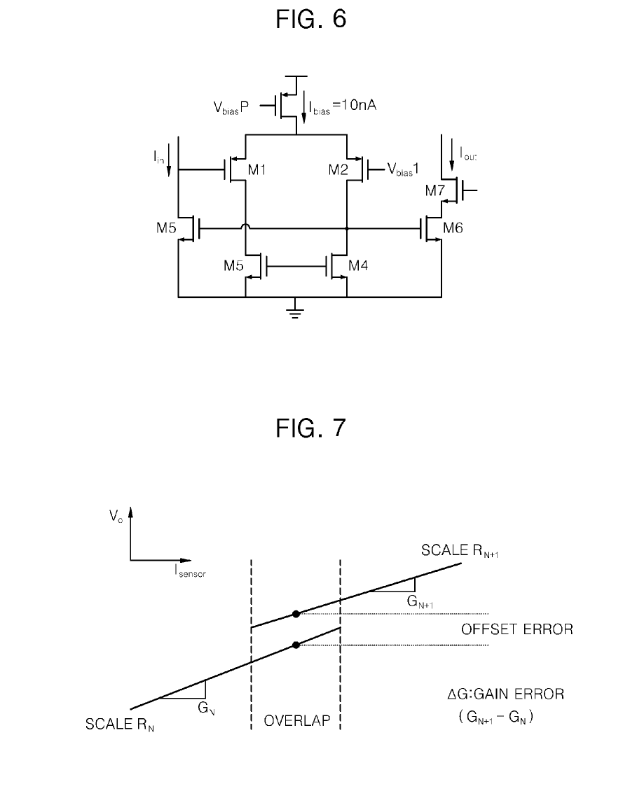

FIG. 6 is a circuit diagram illustrating the AICM constituting the current input unit 310.

M1 to M4 of FIG. 6 may be a general differential amplifier, and may be designed to have sufficient gain and bandwidth according to characteristics of a sensor.

When an input current signal Iᵢₙ of the sensor flows through MOSFETs M5 and M6, the input current signal Iᵢₙ may be amplified according to the CMR. The CMR may be defined as M6/M5, and the MOSFETs M5 and M6 may be designed to operate in a weak inversion region in order to make the MOSFETs M5 and M6 have a wide input range. At the same time when the current is amplified, a voltage of a node to which the input current signal Iᵢₙ is input may be fixed as V_{bias1} by the differential amplifier.

Meanwhile, a MOSFET M7 may operate as a multiplexer together with a decoder, and since linearity is reduced when a large current flows by a resistance component of M7, it may be desirable that the MOSFET be designed to have a large channel width.

Further, the AICM may be oscillated when the current of the sensor is small, and a condition when there is no oscillation may be expressed by Equation 1 below.

$$( {C}_{gd 5} \cdot {g}_{m 5} - {g}_{ma} ) > \frac{{g}_{m 5} \cdot {g}_{ma}}{{w}_{a}} \qquad [ Equation 1 ]$$

Here, C_{gd5} may represent a capacitance between a gate and a drain of the MOSFET M5, gₘ₅ may represent a transconductance of the MOSFET M5, gₘₐ may represent a transconductance of the AMP1, and wₐ may represent −3 dB pole of the AMP1.

Further, C_{c} may be inserted into the AICM for stability. Moreover, a bias current value I_{bias} of the AICM may be set as a value capable of having a very small gₘₐ, for example, 10 nA, in order to increase the stability.

Referring to FIG. 5 again, the current conversion unit 320 may convert each of the current signals amplified by the current input unit 310 into an amplified voltage signal using a plurality of feedback resistors R1 to R3 and an operational amplifier AMP2 that are connected in parallel.

Each of the plurality of feedback resistors R1 to R3 may be connected in series to a switch, and when the switch is closed, each of the plurality of feedback resistors R1 to R3 may be connected to the AMP2 in parallel.

Specifically, the current conversion unit 320 may selectively control a plurality of switches connected in series to the plurality of feedback resistors R1 to R3, respectively, and select at least one of the plurality of feedback resistors R1 to R3 to reduce nonlinearity of the amplified voltage signal.

Meanwhile, each voltage signal amplified by the current conversion unit 320 may have a nonlinear component.

FIG. 7 is a graph illustrating nonlinear characteristics of a voltage signal amplified by the current conversion unit 320.

The nonlinear component may occur due to layout mismatch between the feedback resistors, a process variation, and a parasitic resistance component of the switch, etc. First, a nonlinear problem due to an offset error may be overcome by designing to allow input and output sections between the feedback resistors to be overlapped.

A gain error may occur due to the layout mismatch between a parasitic resistance of the switch for selecting the feedback resistors and each feedback resistor.

To prevent the errors, a parasitic resistance value of the switch may be designed to increase a channel width of a MOSFET constructing the switch, and at the same time to have its channel width which is inversely proportional to the resistance value of the MOSFET. Further, the nonlinearity may be reduced through a layout method, etc. including a dummy cell arrangement, a symmetrical arrangement, etc.

The following table 1 may show a resistance value and a size of the switch optimized for reducing the nonlinearity according to a range of an input current.

TABLE 1

| | Range of | | |
|---|---|---|---|
| | Input Current | Resistance Value | Size of Switch |
| Rf | (A) | (kΩ) | (W/L) |
| R1 | 10 n to 110 n | 1500 | 1μ/0.13μ |
| R2 | 100 n to 1100 n | 150 | 10μ/0.13μ |
| R3 | 1000 n to 10000 n | 15 | 100μ/0.13μ |

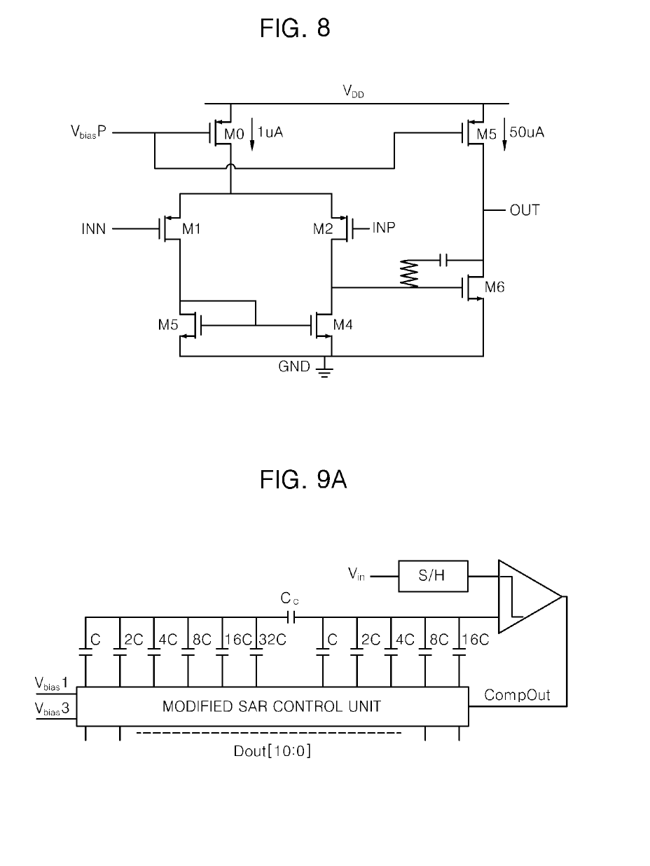

FIG. 8 is a circuit diagram illustrating the operational amplifier AMP2 included in the current conversion unit 320.

A general miller compensation two-stage operational amplifier may be used as the AMP2. The MOSFETs M5 and M6 having a wide channel width may be used as an output stage to drive a current when an input of a sensor is the greatest.

Referring to FIG. 5 again, the digital conversion unit 330 may convert each of the amplified voltage signals converted by the current conversion unit 320 into a digital value. Specifically, the digital conversion unit 330 may convert each of the amplified voltage signals into the digital value by a successive approximation register-analog to digital converter (SAR-ADC), and increase the number of non-converted lower bits in proportion to a value of an upper bit according to a predetermined resolution.

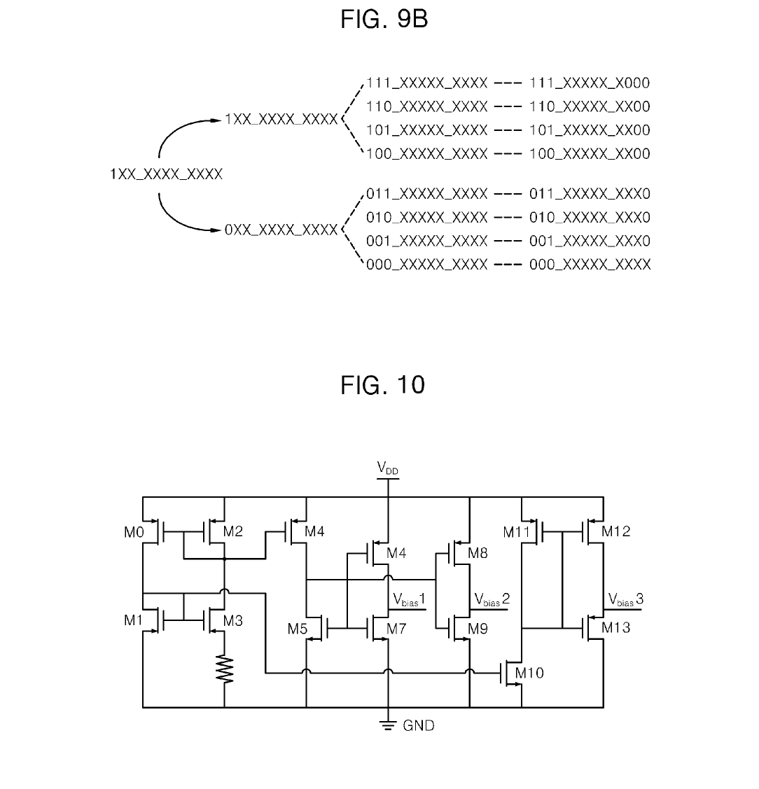

FIGS. 9A and 9B are diagrams illustrating a circuit and an operation method of the digital conversion unit 330.

Referring to FIGS. 9A and 9B, FIG. 9A illustrates a circuit diagram of the digital conversion unit 330. An 11-bit SAR-ADC among N-bit ADCs may be used as the digital conversion unit 330. FIG. 9B illustrates an operation method of the digital conversion unit 330.

When comparing with an input voltage Vᵢₙ, a DC voltage of the current conversion unit 320 may be offset by using V_{bisas1} as a reference voltage. The digital conversion unit 330 may require an 8-bit resolution on the basis of an initial value.

However, the lower bits may not be required since a high resolution is not required in a high input voltage range. Accordingly, an operation of the SAR-ADC may be converted as shown in FIG. 9B in the digital conversion unit 330. The converted operation may reduce power consumption by increasing the number of non-converted lower bits in proportion to a value of upper 3-bit.

Referring to FIG. 5 again, the voltage applying unit 340 may generate voltages for driving each of the multi-sensor array, the current input unit 310, the current conversion unit 320, and the digital conversion unit 330, and apply the generated voltages thereto.

FIG. 10 is a circuit diagram illustrating a detailed construction of the voltage applying unit 340.

Referring to FIG. 10, the voltage applying unit 340 may be a DC bias voltage generating circuit. Generally, the DC bias voltage generating circuit should have characteristics insensitive to process, voltage, temperature variations. When the DC bias voltage generating circuit has characteristics very sensitive to process, voltage, temperature variations, an output voltage may be saturated in the current conversion unit 320.

The current detection device 300 according to the present invention should operate in a very small temperature change environment since a biomaterial is sensitive to the temperature. Further, low heat may be generated since the current detection device 300 operates with low power consumption.

Accordingly, the current detection device 300 according to the present invention should be insensitive to process and supply voltage variations. For this, the current detection device 300 may be designed to be insensitive to the voltage variation through a bias circuit including MOSFETs M0 to M3 which is independent to power supply, and to be insensitive to the process variation using MOSFETs M6 to M9 and M11 to M13 having a threshold voltage Vₜₕ different from each other.

Further, the voltage applying unit 340 may include a buffer for preventing a reaction when applying voltages to the multi-sensor array, the current input unit 310, the current conversion unit 320, and the digital conversion unit 330.

As described above as the problem of the conventional art, the current detection device 300 according to the present invention may require area minimization in order to reduce product costs for detecting signals of a plurality of sensors.

When a two-stage amplifier structure according to the present invention has the same output voltage, a current mirror area of an active input current mirror and an area of R_{f} may have a tradeoff relationship by the CMR, and the relationship may be expressed below by the following Equation 2.

$${A}_{total} = 64 \cdot ( CMR + 1 ) \cdot {A}_{mirror} + \frac{{A}_{resistor}}{CMR} \qquad [ Equation 2 ]$$

Here, 64 represents the number of sensors included in the multi-sensor array, Aₜₒₜₐₗ represents an entire area, Aₘᵢᵣᵣₒᵣ represents an active area of a MOSFET constituting a current mirror in the AICM, and Aᵣₑₛᵢₛₜₒᵣ represents an area of the feedback resistor needed when the CMR is 1. An area of the amplifier may be excluded from the Equation 2 since it is not related to the ratio.

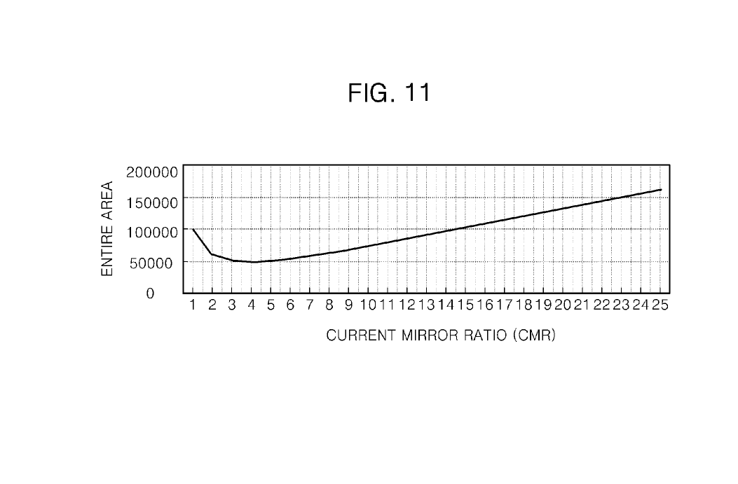

FIG. 11 is a graph illustrating a change of an entire area according to the CMR.

Referring to FIG. 11, the CMR may be set as 4 in order to implement a minimum area.

Referring to FIG. 3 again, the control unit 400 may sequentially apply the plurality of amplified current signals to the current conversion unit 320, and set a gain of the AMP2. That is, the control unit 400 may control an entire process that the detection unit 300 detects the currents.

The transmission unit 500 may transmit the converted digital value to the user terminal 600 which desires to detect the currents of the multi-sensor array.

A test was performed to estimate performance of the present invention. An average power consumption was measured at an operation speed of 640 sample/s using a measurement apparatus for measuring the power consumption. Further, the control unit 400 and the transmission unit 500 manufactured using another process were excluded in measurements of the power consumption and the area. The current detection device 300 according to the present invention was implemented using a 0.13 μm process for detecting a signal of a 64 CNT-sensor array.

The following Table 2 shows performance comparison between the current detection device 300 of the present invention and the detection devices introduced in conventional papers.

TABLE 2

| | | | | | The |
|---|---|---|---|---|---|
| | | | | | present |
| Item | (1) | (2) | (3) | (4) | invention |
| Process(μm) | 0.18 | Off-chip | 0.35 | 0.35 | 0.13 |
| Channel | 24 | 2 | 1 | 4 | 64 |
| Area(mm²) | 0.721 | X | 0.42 | 3.1 | 0.173 |
| Area/ | 0.0300 | X | 0.42 | 0.7750 | 0.0027 |
| Channel | | | | | |
| Resistance | 10K to | 10K to | 1K to | 100 to | 10K to |
| Range | 9M | 10 G | 1 G | 20M | 10M |
| Current | | | | | 10 nA to |
| Range | | | | | 10 μA |
| Supply | 1.2(analog) | +−5 | 3.3 | 3.3 | 1 |
| Voltage(V) | 0.5(digital) | | | | |
| Power | 32μ | 600 m | 15 m | 6 m | 77.06μ |
| Consump- | | | | | |
| tion(W) | | | | | |
| Power/ | 1.33μ | 300 m | 15 m | 1.5 m | 1.20μ |
| Channel | | | | | |
| (W/C) | | | | | |
| Sampling | 1.83K | Resis- | Resis- | 100 | 640 |
| Ratio | | tance | tance | | |
| (S/s) | | Depen- | Depen- | | |
| | | dence | dence | | |

In the Table 2, (1) is a device described in a conventional paper titled “A 32-μW 1.83-kS/s CNT Chemical Sensor System” disclosed by Taeg Sang Cho and Kyeong-Jae Lee in 2009, (2) is a device described in a conventional paper titled “A low-cost interface to high-value resistive sensors varying over a wide range” disclosed by A Flammini and D. Marioli in 2004, (3) is a device described in a conventional paper titled “A 141-dB Dynamic Range CMOS Gas-Sensor Interface Circuit Without Calibration With 16-Bit Digital Output Word” disclosed by M. Grassi and P. Malcovati in 2007, and (4) is a device described in a conventional paper titled “A 160 dB Equivalent Dynamic Range Auto-Scaling Interface for Resistive Gas Sensors Arrays” disclosed by M. Grassi and P. Malcovati in 2007.

The current detection device 300 according to the present invention may consume power of 77.06 μW at the supply voltage of 1 V and the operation speed of 640 sample/s. Further, a linearity error may be lower than or equal to 0.53% in a current range of 10 nA to 10 μA.

As a result, the current detection device 300 according to the present invention has greatly improved performance in power consumption per channel and area compared to the conventional current detection devices.

Accordingly, the present invention may have a low power and small area structure with respect to a multi-sensor array, and can be used to an application of a portable sensor system of the multi-sensor array for detecting various materials.

According to the current detection device for the multi-sensor array in the present invention, the current detection device may have a low power and small area structure with respect to the multi-sensor array, and thus can be used to an application of a portable sensor system of a multi-sensor array for detecting various materials.

While exemplary embodiments have been illustrated and described above, the inventive concept is not limited to the aforementioned specific exemplary embodiments. Those skilled in the art may variously modify the exemplary embodiments without departing from the gist of the inventive concept claimed by the appended claims and the modifications are within the scope of the claims.

1. A current detection device, comprising:
a current input unit configured to amplify a plurality of current signals input from a multi-sensor array according to a predetermined current mirror ratio, and fix each of node voltages to which the plurality of current signals are input;
a current conversion unit configured to convert each of the amplified current signals into an amplified voltage signal using a plurality of feedback resistors and an operational amplifier which are connected in parallel;
a digital conversion unit configured to convert each of the amplified voltage signals converted by the current conversion unit into a digital value; and
a voltage applying unit configured to generate voltages for driving each of the multi-sensor array, the current input unit, the current conversion unit, and the digital conversion unit, and apply the generated voltages thereto.

2. The current detection device of claim 1, wherein the current input unit amplifies each of the plurality of current signals according to the current mirror ratio, and comprises a plurality of active input current mirrors corresponding to the number of sensors constituting the multi-sensor array.

3. The current detection device of claim 1, wherein the current conversion unit selectively controls a plurality of switches which are serially connected to the plurality of feedback resistors, respectively, and selects at least one of the plurality of feedback resistors for reducing nonlinearity of the amplified voltage signal.

4. The current detection device of claim 1, wherein the digital conversion unit converts each of the amplified voltage signals into the digital value by a successive approximation register-analog to digital converter (SAR-ADC), and increases the number of non-converted lower bits in proportion to a value of an upper bit by a predetermined resolution.

5. The current detection device of claim 1, further comprising:
a control unit configured to sequentially apply the plurality of amplified current signals to the current conversion unit, and set a gain of the operational amplifier; and
a transmission unit configured to transmit the converted digital value to a user terminal which desires to detect currents of the multi-sensor array.

6. The current detection device of claim 1, wherein the current input unit fixes each of the node voltages by an active input current mirror.

7. The current detection device of claim 2, wherein the current conversion unit selectively controls a plurality of switches which are serially connected to the plurality of feedback resistors, respectively, and selects at least one of the plurality of feedback resistors for reducing nonlinearity of the amplified voltage signal.

8. The current detection device of claim 2, wherein the digital conversion unit converts each of the amplified voltage signals into the digital value by a successive approximation register-analog to digital converter (SAR-ADC), and increases the number of non-converted lower bits in proportion to a value of an upper bit by a predetermined resolution.

9. The current detection device of claim 2, further comprising:
a control unit configured to sequentially apply the plurality of amplified current signals to the current conversion unit, and set a gain of the operational amplifier; and
a transmission unit configured to transmit the converted digital value to a user terminal which desires to detect currents of the multi-sensor array.
